(19) United States
(12) Patent Application Publication
(10) Pub. No.: US 2016/0218228 A1
(43) Pub. Date: Jul. 28, 2016

(54) PHOTOVOLTAIC AND DIRECT THERMAL APPARATUS AND METHODS

(71) Applicant: HEWLETT-PACKARD DEVELOPMENT COMPANY, L.P., Houston, TX (US)

(72) Inventors: Morad M. SAMII, La Jolla, CA (US); Matthew D. NUTH, Ramona, CA (US)

(21) Appl. No.: 15/087,611

(22) Filed: Mar. 31, 2016

Related U.S. Application Data
(62) Division of application No. 13/789,013, filed on Mar. 7, 2013.

(51) Int. Cl. H01L 31/024; H01L 31/18; H01L 31/02; H02S 40/42

(52) U.S. Cl. CPC H01L 31/024; H02S 40/425; H01L 31/18; H01L 31/02008

(57) ABSTRACT

Apparatus and methods related to solar energy are provided. A metallic entity has a photovoltaic material in contact therewith. The metallic entity at least partially defines a fluid conduit. An electrode pattern is in contact with the photovoltaic material. Electrical energy generated by the photovoltaic material is coupled to an electrical load by way of the metallic entity and the electrode pattern. Thermal energy is conducted through the metallic entity and is transferred to a fluid coolant flowing through the fluid conduit. Various hybrid photovoltaic and direct thermal energy apparatuses are therefore contemplated.

### BACKGROUND

Photovoltaic (PV) devices generate electrical energy by direct conversion of photonic energy. Improvements in PV operating performance and economy of manufacture are continuously sought after. The present teachings address the foregoing and related concerns.

### BRIEF DESCRIPTION OF THE DRAWINGS

The present embodiments will now be described, by way of example, with reference to the accompanying drawings, in which:

FIG. 1 depicts a diagram of a photovoltaic and direct thermal apparatus according to one example of the present teachings;

FIG. 2 depicts an end elevation of a portion of an apparatus according to another example;

FIG. 3 depicts a diagram of a photovoltaic and direct thermal apparatus according to another example of the present teachings;

FIG. 4 depicts an end elevation of a portion of an apparatus according to another example;

FIG. 5 depicts a diagrammatic view of a system according to yet another example of the present teachings;

FIG. 6 depicts a flow diagram of a method according to an example of the present teachings;

FIG. 7 depicts a flow diagram of a method according to another example;

FIG. 8 depicts a schematic of a fluid coolant heat transfer system according to one example of the present teachings;

FIG. 9 depicts a schematic of a fluid coolant heat transfer system according to another example; and

FIG. 10 depicts a flow diagram of a method according to another example of the present teachings.

### DETAILED DESCRIPTION

### Introduction

Systems and methods related to solar energy are provided. Photovoltaic structures are designed to maximize heat transfer to a fluid coolant. The efficiency of the cooling system is such that usable quantities of heat are ejected (transported) from the structure. This serves at least two objectives: 1) Increasing the overall efficiency of PV cells by lowering their average operating temperature; and 2) extracting usable thermal energy through more efficient cooling system design and operation,

The present teachings contemplate concentrated collector and flat collector schemas. Additionally, the present teachings are directed to using, where possible, the most cost effective and established industrial processes such as sheet metal forming, roll coatings, conductive ink printing, and the use of existing standard components. Furthermore, quantum dot, nano-particle, and other photovoltaic materials are applied to generate electrical energy by direct conversion.

In one example, an apparatus includes a metallic entity that is electrically conductive and thermally conductive. The metallic entity at least partially defines a fluid conduit. The apparatus also includes a photovoltaic coating in electrically conductive contact with the metallic entity. The apparatus further includes an electrode pattern in electrically conductive contact with the photovoltaic coating.

In another example, a method includes providing a photovoltaic apparatus having a photovoltaic coating in contact with a metallic entity. The metallic entity at least partially defines a fluid conduit. The method also includes conducting electrical current generated by the photovoltaic apparatus through an electrical load. The method further includes transferring thermal energy conducted through the metallic entity to a fluid coolant flowing through the fluid conduit.

### First Illustrative Apparatus

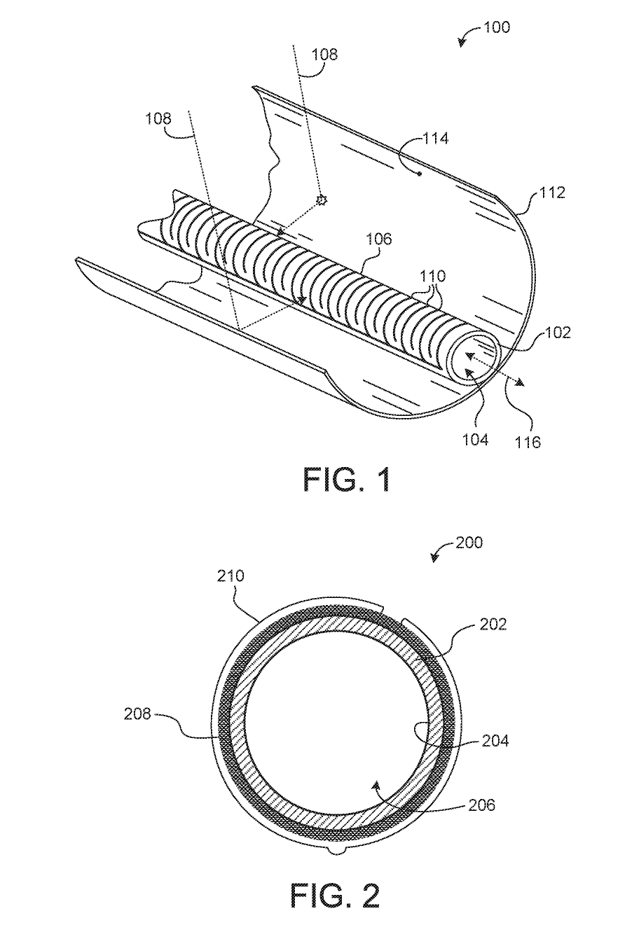

Attention is directed now to FIG. 1, which depicts an apparatus 100 in accordance with an illustrative embodiment of the present teachings. Other apparatus having respectively varying constituencies or configurations can also be used. The apparatus 100 can also be referred to as a (hybrid) photovoltaic and direct thermal energy apparatus 100 for purposes herein.

The apparatus 100 includes a metallic entity (or tube) 102. The tube 102 can be formed from any suitable electrically and thermally conductive material such as, without limitation, copper, aluminum, stainless steel, brass, and so on. Other materials can also be used. The tube 102 defines a fluid conduit 104 bounded by an internal surface.

The apparatus 100 includes a photovoltaic (PV) material 106 borne on the metallic entity 102. The PV material 106 is in direct, electrically conductive contact with an outer surface of the tube 102. The PV material 106 can be defined by a “quantum dot” material, or another emulsion suspension-base nano-particle material. Non-limiting examples of such materials can be obtained from Nanosolar, Inc, San Jose, Calif., USA. In one example, the PV material 106 is applied by dip coating the metallic entity 102. Other suitable application techniques can also be used. The PV material 106 generates electrical energy by direct conversion of incident photonic energy (e.g., sunlight) as depicted by illustrative rays 108.

The apparatus 100 also includes an electrode pattern 110 formed on the outward surface of the PV material 106. The electrode pattern 110 can be formed from any suitable electrically conductive material such as a conductive ink having metallic particles therein. In one example, the electrode pattern 110 is formed or deposited on the PV material 106 by way of an ink-jet printing technique. A plurality of different electrode patterns 110 can be used, as can various application techniques. Non-limiting examples of such techniques include direct application of predefined patterns, silk-screening, and so on.

The electrode pattern 110 defines an electrical node of a first polarity (e.g., positive), while the metallic entity 102 defines an electrical node of a second polarity (e.g., negative) opposite to the first. Thus, the metallic entity 102 also defines a “ground plane” in accordance with at least some examples of the present teachings. Electrical energy generated by the PV material 106 can be communicated to a load device by way of connecting or coupling it to the electrode pattern 110 and the metallic entity 102.

The apparatus 100 further includes a reflective light concentrator (concentrator) 112. The concentrator 112 is characterized by a parabolic cross-sectional shape and includes a reflective inner surface 114. Other light concentrator geometries, cross-sections, orientations or form factors can also be used. In one example, the concentrator 112 is formed from thermoplastic and bears a reflective aluminum coating on the inner surface 114, over-coated with a protective, transparent silicon dioxide layer. In another example, the concentrator 112 is formed from aluminum sheet metal that is polished and over-coated to provide the reflective inner surface 114. Other suitable materials or fabrication techniques can also be used.

Normal, typical operations of the apparatus 100 are generally as follows: the apparatus 100 is located such that sunlight 108 is concentrated upon the PV material 106 (and to the metallic tube 102 by thermal communication) by way of the concentrator 112. Electrical energy generated by the PV material 106 is provided to an electrical load entity (described hereinafter) by way of coupling to the metallic entity 102 and electrode pattern 110. The PV material 106 is also referred to as an “absorption surface” by virtue of its exposure to photonic energy during typical normal use.

Fluid coolant, such as water, water/ethylene glycol mix, or another suitable fluid, flows through the fluid conduit 104 defined by the metallic tube 102. Thermal energy (i.e., heat), due to the concentrated solar energy incident to the PV material 106, is conducted through the metallic tube 102 and transferred to the fluid flow 116. Such thermal energy can be again transferred to another fluid or thermal mass, stored in suitable media, and so on.

PV material 106 generally operates more efficiently at lower temperatures (i.e., there is greater energy yield per unit surface area). A temperature gradient typically occurs across (or along) the flow axis of the apparatus 100 due to the relatively cooler entering fluid compared to the warmer exiting fluid. Thus, an efficiency gradient can also exist, with the cooler portion of the PV material 106 yielding more energy per unit area than the warmer portion of the PV material 106. PV materials that operate at relatively greater temperatures can also exhibit reduced useful lifespan, especially under concentrated photonic exposure.

In view of the foregoing, coolant flow 116 can be run in either direction. Alternatively, the direction of flow 116 can be run in one direction, and then in the opposite direction, periodically switching back and forth between the two respective directions. In one example, the temperature of the coolant exiting the fluid conduit (e.g., PV apparatus) is measured and a rate of temperature increase is compared to a threshold rate value. When the exiting coolant is in “thermal steady-state”, as evidenced by a negligible (minimal, or zero) rate of change in temperature, the coolant flow direction is reversed and maintained until thermal steady-state is once again detected. And so on. Other cooling control strategies can also be used.

### First Illustrative End Elevation

Reference is made now to FIG. 2, which depicts an end elevation (or end cross-section) of a PV and direct thermal apparatus (apparatus) 200 in accordance with an illustrative embodiment of the present teachings. Other apparatus having respectively varying constituencies or configurations can also be used. In one example, the PV apparatus 200 is equivalent (or analogous) to a portion of the apparatus 100.

The apparatus 200 includes a metallic tube 202. The metallic tube 202 has a circular cross-sectional shape and is formed from metal such as copper, aluminum, or another suitable electrically and thermally conductive material. An inner surface 204 of the metallic tube 202 defines a central coolant passageway or fluid conduit 206. Other tubes having respective, suitable cross-sectional shapes (square, rectangular, oval, and so on) can also be used.

The apparatus 200 also includes a photovoltaic material 208 applied to and in contact with an outer surface of the metallic tube 202. The PV material 208 can be formed from or defined by a quantum dot material and can be applied by dip coating. Other suitable materials (e.g., nano-particle emulsion/suspension, and so on) or application techniques can also be used. The metallic tube 202 functions as an electrical node (e.g., ground plane) with respect to the PV material 208.

The apparatus 200 further includes an electrode pattern 210 applied to and in contact with an outer surface of the PV material 208. The electrode pattern 210 can be formed by way of ink-jet printing an electrically conductive ink. Other suitable materials, electrode patterns, or application techniques can also be used. The electrode pattern 210 functions as an electrical node (e.g., positive node) with respect to the PV material 208.

### Second Illustrative Apparatus

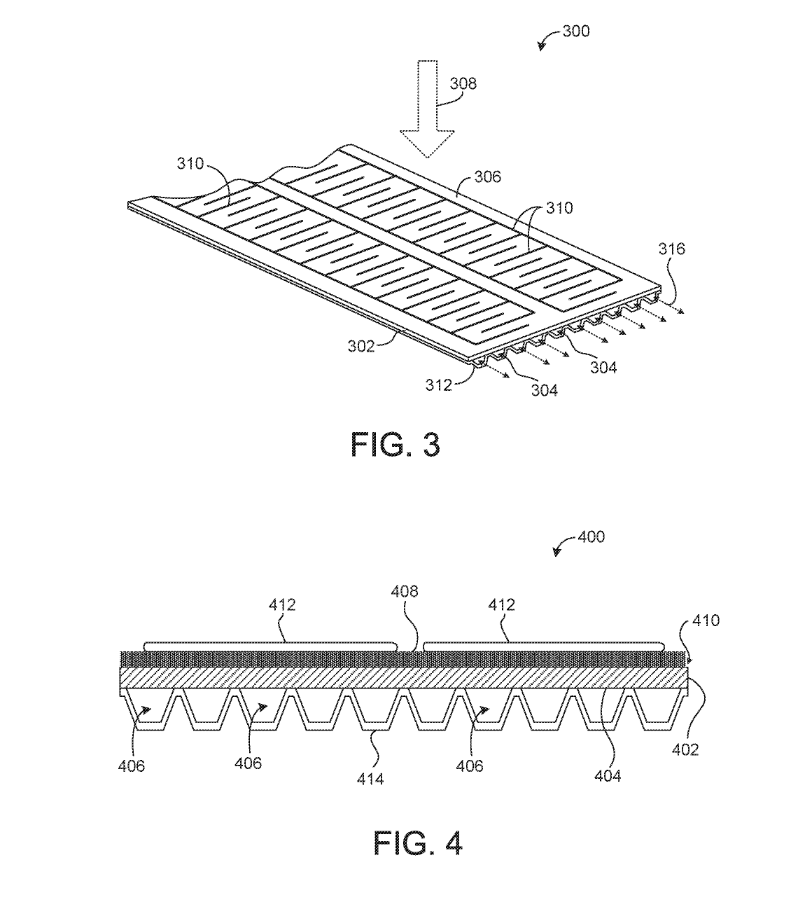

Attention is now directed to FIG. 3, which depicts an apparatus 300 in accordance with an illustrative embodiment of the present teachings. Other apparatus having respectively varying constituencies or configurations can also be used. The apparatus 300 is also referred to as a photovoltaic and direct thermal apparatus 300 for purposes herein.

The apparatus 300 includes a metallic entity (plate, or platen) 302. The plate 302 can be formed from any suitable electrically and thermally conductive material such as, without limitation, copper, aluminum, stainless steel, brass, and so on. Other materials can also be used. The plate 302 is characterized by a surface that partially defines a plurality of fluid conduits 304.

The apparatus 300 includes a photovoltaic (PV) material 306 borne on the metallic entity 302. The PV material 306 is in direct, electrically conductive contact with an outer surface of the plate 302. The PV material 306 can be defined by a “quantum dot” material, a nano-particle emulsion/suspension material, or another suitable material. In one example, the PV material 306 is applied by way of roll-to-roll coating the metallic plate 302. Other suitable application techniques can also be used. The PV material 306 generates electrical energy by direct conversion of incident photonic energy (e.g., sunlight, or solar flux) 308.

The apparatus 300 also includes an electrode pattern 310 formed on the outward surface of the PV material 306. The electrode pattern 310 can be formed from any suitable electrically conductive material such as a conductive ink as illustrated above. In one example, the electrode pattern 310 is formed or “imaged” on the PV material 306 by way of an ink-jet printing technique. Other suitable application or printing techniques can also be used.

The electrode pattern 310 defines an electrical node of a first polarity (e.g., positive), while the metallic entity (plate) 302 defines an electrical node of a second polarity (e.g., negative) opposite to the first. Thus, the metallic entity 302 also defines a “ground plane” in accordance with at least some examples of the present teachings. Electrical energy generated by the PV material 306 can be communicated to a load device by way of coupling it to the electrode pattern 310 and the metallic entity 302.

The apparatus 300 further includes a corrugated metal sheet (CMS) 312. The CMS 312 is characterized by a repeating pattern of folds so as to define a plurality of parallel troughs. The CMS 312 can be folded in accordance with a number of different suitable shapes. In one example, the CMS 312 is formed from the same material as the metallic entity 302 and is bonded or joined there to such that the plural fluid conduits 304 are defined. Such bonding can be by way of soldering, welding, epoxy, and so on. Other suitable materials or techniques can also be used.

Normal, typical operations of the apparatus 300 are generally as Follows: the apparatus 300 is located such that sunlight 308 is incident upon the PV material 306. Electrical energy generated by the PV material 306 is provided to an electrical load entity (described hereinafter) by way of coupling to the metallic entity 302 and electrode pattern 310. Fluid coolant flow 316 is routed through the fluid conduits 304 defined by the metallic plate 302 and the corrugated metal sheet 312. Thermal energy is conducted through the metallic entity 302 and transferred to the fluid flow 316. Such thermal energy can be again transferred to another fluid or thermal mass, stored in suitable media, and so on.

The coolant flow 316 can be run in either direction, or the flow 316 can be run in one direction and then the other, switching back and forth between the two respective directions. In one example, the temperature of the coolant exiting the fluid conduits 304 is measured and a rate of temperature increase is used to determine direction of flow, generally as described above. Other cooling control strategies can also be used.

### Second Illustrative End Elevation

Reference is made now to FIG. 4, which depicts an end elevation of a PV and direct thermal apparatus (apparatus) 400 in accordance with an illustrative embodiment of the present teachings. In one example, the PV apparatus 400 is equivalent or analogous to the PV apparatus 300 described above. Other apparatus having respectively varying constituencies or configurations can also be used.

The apparatus 400 includes a metallic plate 402. The metallic plate 402 can be formed from copper, aluminum, stainless steel or another suitable electrically and thermally conductive material. A lower surface 404 of the metallic plate 402 defines a portion of a plurality of fluid conduits (or passageways) 406.

The apparatus 400 also includes a photovoltaic material 408 applied to and in contact with an upper surface 410 of the metallic plate 402. The PV material 408 can be formed from or defined by a quantum dot material, and can be applied by roll-to-roll coating. Other suitable materials or application techniques can also be used. The metallic plate 402 functions as an electrical node (e.g., ground plane) with respect to the PV material 408.

The apparatus 400 further includes an electrode pattern 412 applied to and in contact with an outer surface of the PV material 408. The electrode pattern 412 can be formed by way of ink-jet printing an electrically conductive ink. Other suitable materials or application techniques (e.g., silk-screening, direct pattern transfer, and so on) can also be used. The electrode pattern 412 functions as an electrical node (e.g., positive node) with respect to the PV material 408.

The apparatus 400 further includes a CMS 414. The CMS 414 can be formed from the same material as the metallic plate 402, or another material that is compatible therewith. The CMS 414 is characterized by a pattern of folds such that a plurality of parallel troughs is defined, each defining a portion of a respective fluid conduit 406. The CMS 414 can be bonded to the lower surface 404 of the metallic plate 402 by way of soldering, welding, epoxy or another adhesive, and so on.

### Illustrative System

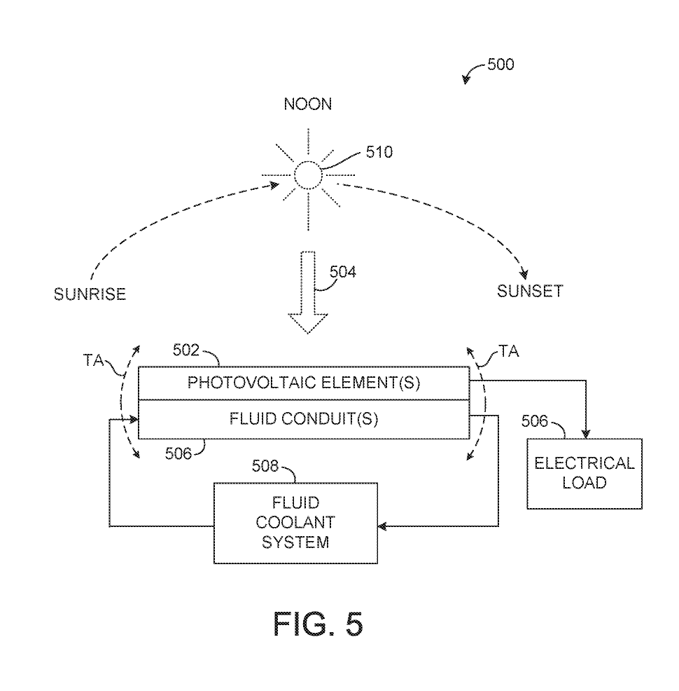

Attention is directed now to FIG. 5, which depicts a system 500 in accordance with the present teachings. The system 500 is illustrative and non-limiting, and other system having respectively varying constituencies or configurations can also be used.

The system 500 includes one or more PV elements 502. Each PV element 502 includes a metallic entity in the form of a plate or tube, bearing a PV material in contact there with. Each PV element 502 also includes an electrode pattern formed on the PV material, Solar flux 504 causes the generation of electrical energy that is provided to an electrical load 506. The electrical load 506 is electrically coupled to the metallic entity and electrode pattern of each of the PV elements 502. In turn, the electrical load 506 can include any suitable elements or configuration. Non-limiting examples of such elements include storage batteries, a charge controller, a voltage regulator, a power inverter, utility line interconnect equipment, and so on. Other suitable electrical constituency can also be used.

The system 500 also includes one or more fluid conduits 506, each being defined (at least in part) by the metallic plate or tube of a corresponding PV element 502. The system 500 also includes a fluid coolant system 508. The fluid coolant system 508 can include any suitable constituency including, but not limited to: a controller, valves, a heat exchanger, thermal storage media, temperature sensors, a pump, a fluid reservoir, and so on. Other suitable elements can also be used.

The fluid coolant system 508 is coupled to drive (induce, or cause) a flow of fluid coolant through the fluid conduit(s) 506 such that thermal energy is transferred through the metallic entities of the PV elements 502 and into the flow of fluid coolant. Such thermal energy can be transferred to a storage media, transferred to another fluid by heat exchanger, and so on.

The system 500 depicts just one of any number of system topologies that can include and use PV apparatus and fluid coolant strategies according to the present teachings. The PV element(s) 502 and associated fluid conduit(s) 506 can be driven to track the apparent motion of the sun 510, as indicated by arcuate arrows “TA”. Such tracking can be single axis or dual axis. In another example, the system 500 is supported in a fixed manner and tracking is not performed. Other suitable operating strategies can also be used.

### First Illustrative Method

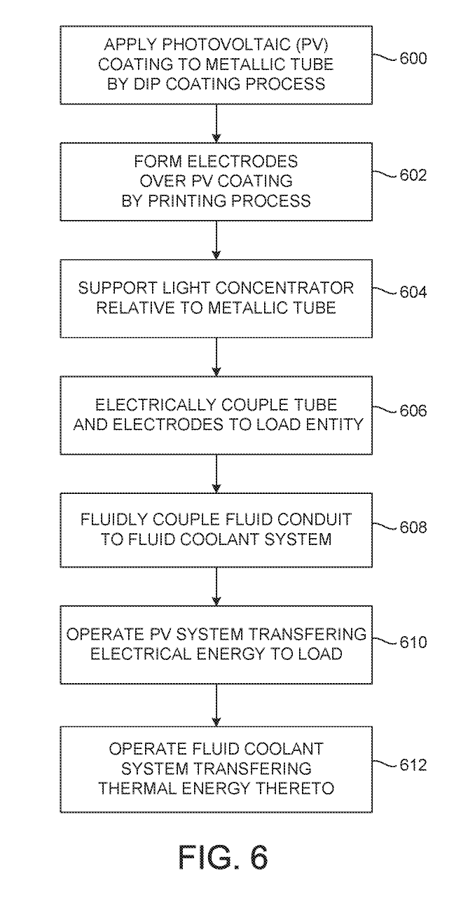

Reference is made now to FIG. 6, which depicts a flow diagram of a method according to the present teachings. The method of FIG. 6 includes particular steps performed in a particular order of execution. However, other methods including other steps, omitting one or more of the depicted steps, or proceeding in other orders of execution can also be defined and used. Thus, the method of FIG. 6 is illustrative and non-limiting with respect to the present teachings. Reference is also made to FIGS. 1, 2 and 5 in the interest of illustrating the method of FIG. 6.

At 600, a photovoltaic coating is applied to a metallic tube by a dip coating process. For purpose of a present example, a metallic tube 102, formed from copper, is dip coated into a quantum dot material such that a PV coating (material) 106 is formed on, and in contact with, an outside surface thereof. An inner surface (e.g., 204) of the metallic tube 102 remains uncoated during the PV material application process and defines the bounding surface of fluid conduit 104.

At 602, electrodes are formed over the PV coating by a printing process. In the present example, an electrically conductive ink is jet-printed onto the PV material 106 applied at step 600 above, forming an electrode pattern 110. The electrode pattern 110 defines an electrical node in contact with the PV material 106. A PV apparatus (e.g., 200), including the metallic tube 102, the PV material 106 and the electrode pattern 110, is thus defined.

At 604, a light concentrator is supported relative to the metallic tube. For purposes of the present example, a light concentrator 112, having a parabolic cross-section and a reflective surface 114, is disposed such that the PV-coated metallic tube 102 is located along the focal region (band, or zone) thereof.

At 606, the metallic tube and the electrodes are electrically coupled to a load entity. In the present example, an electrical load 506, including a storage battery and a battery charge controller, are coupled to the metallic tube 102 and the electrode pattern 110.

At 608, a coolant system is fluidly coupled to the fluid conduit. In the present example, a fluid coolant system 508, including a pump and a heat exchanger and a mass of water/glycol mix, is fluidly coupled to the fluid conduit 104 defined by the metallic tube 102.

At 610, the PV system is operated so as to transfer electrical energy to the load. In the present example, photonic energy (sunlight) 108 is concentrated on the PV material 106, resulting in the generation of electrical energy. Electrical voltage drives a corresponding current through the electrical load 506, charging the storage battery.

At 612, the fluid coolant system is operated so as to transfer thermal energy thereto. In the present example, thermal energy (i.e., heat) from the PV material 106 is conducted through the metallic tube 102 and transferred to the water/glycol mix flowing through the fluid conduit 104. The corresponding thermal energy is then transferred to another media by way of the heat exchanger of the fluid coolant system 508, and the cooled fluid coolant is circulated back to the metallic tube 102.

### Second Illustrative Method

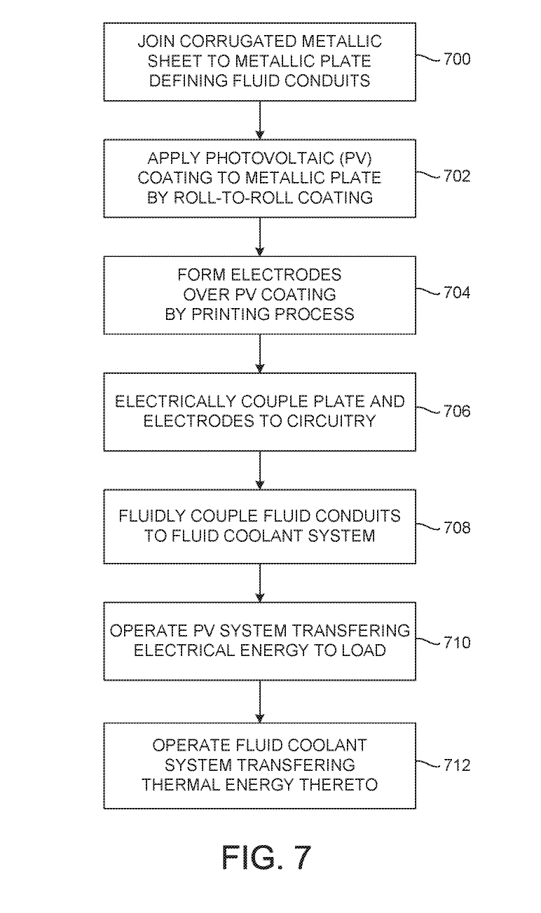

Reference is made now to FIG. 7, which depicts a flow diagram of a method according to the present teachings. The method of FIG. 7 includes particular steps performed in a particular order of execution. However, other methods including other steps, omitting one or more of the depicted steps, or proceeding in other orders of execution can also be defined and used. Thus, the method of FIG. 7 is illustrative and non-limiting with respect to the present teachings. Reference is also made to FIGS. 3, 4 and 5 in the interest of illustrating the method of FIG. 7.

At 700, a corrugated metal sheet is joined to a metallic plate such that fluid conduits are defined. For purposes of the present example, a CMS 312 is bonded or joined to the lower surface of a metallic plate 302 such that a plurality of fluid conduits 304 are defined.

At 702, a photovoltaic coating is applied to the metallic plate by a roll-to-roll process. For purpose of a present example, a quantum dot material is roll-to-roll coated onto the metallic plate 302 such that a PV material 306 is supported on, and in contact with, an upper surface (e.g., 410) thereof. The metallic plate 302 is formed from copper, for purposes of illustration.

At 704, electrodes are formed over the PV coating by a printing process. In the present example, an electrically conductive ink is jet-printed onto the PV material 306 applied at step 702 above, forming an electrode pattern 310. The electrode pattern 310 defines an electrical node in contact with the PV material 306. A PV apparatus (e.g., 400), including the metallic plate 302, the PV material 306, the electrode pattern 310 and the CMS 312, is thus defined,

At 706, the metallic plate and the electrodes are electrically coupled to a load entity. In the present example, an electrical load 506, including a computer and a power inverter, are coupled to the metallic plate 302 and the electrode pattern 310.

At 708, a coolant system is fluidly coupled to the fluid conduits. In the present example, a fluid coolant system 508, including a pump and a heat exchanger and a mass of water/glycol mix, is fluidly coupled to the respective, plural fluid conduits 304 defined by the metallic plate 302 and the CMS 312.

At 710, the PV system is operated so as to transfer electrical energy to the load. In the present example, photonic energy (sunlight) 308 is incident upon the PV material 306, resulting in the generation of electrical energy. A corresponding electrical current through the electrical load 506, energizing the power inverter and the computer.

At 712, the fluid coolant system is operated so as to transfer thermal energy thereto. In the present example, thermal energy (i.e., heat) from the PV material 306 is conducted through the metallic plate 302 and transferred to the water/glycol mix flowing through the plural fluid conduits 304. The corresponding thermal energy is then transferred to another media by way of the fluid coolant system 508, and the cooled fluid coolant is circulated back to the plural fluid conduits 304.

### First Illustrative Fluid Cooling System

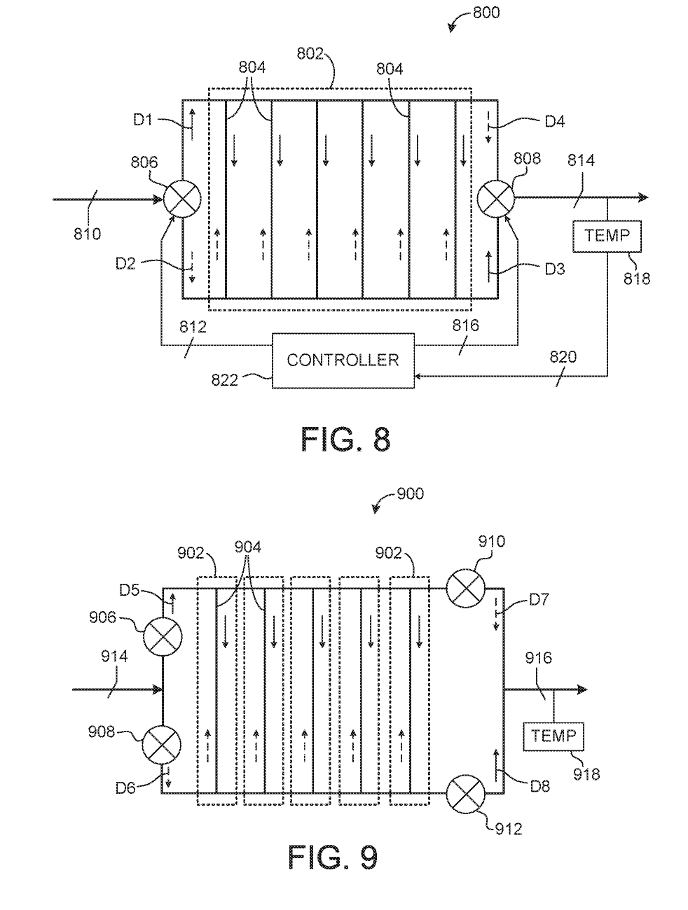

Reference is made now to FIG. 8, which depicts a schematic diagram of a fluid cooling system (system) 800 according to the present teachings. The system 800 is illustrative and non-limiting, and other fluidic cooling systems can also be configured and used according to the present teachings.

The system 800 includes a PV apparatus 802. In one example, the PV apparatus 802 includes a metallic plate (e.g., 402), which at least partially defines a plurality of fluid conduits 804. A total of six, linear fluid conduits 804 are depicted in the interest of clarity. However, other examples respectively defined by other fluid conduit counts or form factors can also be used.

The system 800 also includes respective control valves 806 and 808. Each control valve 806 and 808 is fluidly coupled to opposite ends of each of the fluid conduits 804. Additionally, each control valve 806 and 808 is configured to direct a flow of fluid from (or to) a common port and one of two respective inlet (or outlet) ports in accordance with a respective control signal.

Specifically, the control valve 806 is fluidly connected to receive an input coolant flow 810 at a common port, and to direct that flow in either a direction “D1” or a direction “D2”, according to a control signal 812. In turn, the control valve 808 is fluidly connected to receive a coolant flow from either a direction “D3” or a direction “D4”, and to direct an exit coolant flow 814 outward through a common port, according to a control signal 816.

The system 800 also includes a temperature sensor 818 configured to sense (measure, or detect) a temperature of the exiting coolant flow 814 and to provide a corresponding signal 820. The system 800 further includes a controller 822. The controller 822 is coupled to the control valves 806 and 808 so as to provide the respective control signals 812 and 816. The controller 822 is configured to monitor the exiting coolant flow 814 temperature by way of signal 820 and to operate (or stage) the control valves 806 and 808 accordingly, as described in one example below.

In one illustrative and non-limiting example, the controller 822 is configured to control the valves 806 and 808 in accordance with two distinct operating modes. In a first mode, the valves 806 and 808 are throttled (controlled) so that coolant flow enters the fluid conduits 804 by way of direction D1 and exits by way of direction D3. Thus, the first mode defines a first or “forward” flow direction through the PV apparatus 802. In a second mode, the valves 806 and 808 are controlled so that coolant flow enters the fluid conduits 804 by way of direction D2 and exits by way of direction D4. Thus, the second mode defines a second or “reverse” flow direction through the PV apparatus 802.

The controller 822 is further configured to switch between forward and reverse coolant flow directions (first and second modes) in accordance with the temperature signal 820. Coolant flow is performed in the first mode while the temperature of the exit coolant flow 814 is increasing with time at or greater than a threshold rate. Thereafter, a thermal steady-state condition (or nearly so) is detected, and the controller 822 signals the valves so as to assume the second mode of operation.

When thermal steady-state is again detected, the controller signals the valves 806 and 808 to assume operation in the first mode, and so on. In this way, the thermal gradient across the PV apparatus 802 is cycled back and forth (i.e., “flattened” or averaged) in the interest to longevity and improved operating efficiency. Control in accordance with other stratagems can also be performed.

### Second Illustrative Fluid Cooling System

The Reference is made now to FIG. 9, which depicts a schematic diagram of a fluid cooling system (system) 900 according to the present teachings. The system 900 is illustrative and non-limiting, and other fluidic cooling systems can also be configured and used according to the present teachings.

The system 900 includes five respective a PV apparatuses 902. In one example, each PV apparatus 902 includes a metallic tube (e.g., 202) that defines a fluid conduit 904. Thus, total of five, linear fluid conduits 904 are depicted in the interest of clarity. However, other examples respectively defined by other fluid conduit counts or form factors can also be used.

The system 900 also includes four respective control valves 906, 908, 910 and 912. Each control valve 906-912 is fluidly coupled to control flow through the fluid conduits 904. Additionally, each control valve 906-912 is configured to control a flow of fluid into one port (inlet) and out another port (outlet) in accordance with control signaling.

Specifically, the control valve 906 is fluidly connected to receive an input coolant flow 914 and to pass (or block) that flow in a direction “D5” according to a control signal. In turn, the control valve 912 is fluidly connected to pass (or block) flow in a direction “08” so as to direct an exit coolant flow 916 outward according to a control signal. Coolant flow in the directions D5 and D8 define flow in a first or “forward” direction, or a first mode of operation.

In turn, the control valve 908 is fluidly connected to receive the input coolant flow 914 and to pass (or block) that flow in a direction “D6” according to a control signal. The control valve 910 is fluidly connected to pass (or block) flow in a direction “D7” so as to direct the exit coolant flow 916 outward according to a control signal. Coolant flow in the directions D6 and D7 define flow in a second or “reverse” direction, or a second mode of operation.

The system 900 also includes a temperature sensor 918 configured to sense (measure, or detect) a temperature of the exiting coolant flow 916 and to provide a corresponding signal. The system 900 further can be controlled and operated similarly to that of system 800, by way of sensing the temperature signal from the sensor 918 and staging (or throttling) the valves 906-912 accordingly. A corresponding controller (i.e., 822) and temperature and control signals are omitted from FIG. 9 in the interest of clarity, but can be analogous to those of system 800 described above. Other controller configurations of control stratagems can also be used.

### Third Illustrative Method

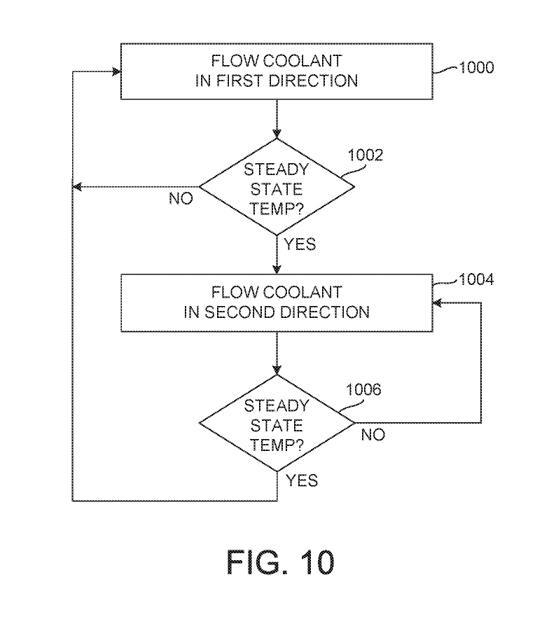

Reference is made now to FIG. 10, which depicts a flow diagram of a method according to the present teachings. The method of FIG. 10 includes particular steps performed in a particular order of execution. However, other methods including other steps, omitting one or more of the depicted steps, or proceeding in other orders of execution can also be defined and used. Thus, the method of FIG. 10 is illustrative and non-limiting with respect to the present teachings. Reference is also made to FIG. 8 in the interest of illustrating the method of FIG. 10.

At 1000, a coolant flows in a first direction. For purposes of a present example, a flow 810 of fluid coolant, including a water/glycol mix, enters a valve 806. A control signal 812 from a controller 822 causes the valve 806 to direct the flow in a direction D1. The fluid coolant flows through respective fluid conduits 804 and is input to a control valve 808. A control signal 816 causes the valve 808 to direct the flow D3 outward as an exit coolant flow 814. The fluid coolant thus flows through a PV apparatus 802 in a first (or forward) direction.

At 1002, it is determined if a coolant is flowing at a steady-state temperature. In the present example, a temperature sensor 818 provides a temperature signal 820 to the controller 822. The controller 822 determines if the temperature of the exit coolant flow 814 is changing at a rate greater than some threshold value (e.g., a value in the range of 1-to-10 Deg. F. per minute). If the temperature of the exit coolant 814 is changing (i.e., rising) at greater than the threshold rate, then steady-state is not detected (determined) and the method returns to step 1000 above. If the temperature of the exit coolant 814 is not changing at greater than the threshold rate, then steady-state is detected and the method proceeds to step 1004 below.

At 1004, a coolant flows in a second direction. For purposes of a present example, a control signal 812 from a controller 822 causes the valve 806 to direct the flow 810 in a direction D2. The fluid coolant flows through the respective fluid conduits 804 and to the control valve 808. A control signal 816 causes the valve 808 to direct the flow D4 outward as the exit coolant flow 814. The fluid coolant thus flows through the PV apparatus 802 in a second (or reverse) direction.

At 1006, it is determined if exit coolant is flowing at a steady-state temperature. In the present example, the controller 822 determines if the temperature of the exit coolant flow 814 is changing at a rate greater than the threshold value by way of the temperature signal 820. If the temperature of the exit coolant 814 is changing at greater than the threshold rate, then steady-state is not detected (determined) and the method returns to step 1004 above. If the temperature of the exit coolant 814 is not changing at greater than the threshold rate, then steady-state is detected and the method proceeds back to step 1000 above.

In general, the present teachings contemplate systems and methods for forming and operating PV and direct thermal apparatuses, and related electrical loads and fluid cooling systems. A PV apparatus includes a metallic plate or metallic tube, which at least partially defines one or more fluid conduits. A PV material, which can be a quantum dot material or a nano-particle material (or suitable other) is applied to a surface of the metallic entity, and then an electrode pattern is formed or printed there over. The metallic entity defines an electrical node of the PV apparatus, while the electrode pattern defines an electrical node of opposite polarity to that of the metallic entity.

A coolant system is used to provide a flow of fluid coolant through the one or more fluid conduits. An electrical load is coupled to the respective electrical nodes of the PV apparatus and receives electrical energy there from during normal, typical operations, In turn, thermal energy is transferred through the metallic entity to the fluid coolant flow within the conduit or conduits. The fluid coolant flow can be re-circulated to the PV apparatus after heat is extracted there from, or the coolant flow can operate according to a single-pass schema.

A flow of fluid coolant can be operated in forward and reverse modes, switching back and forth between the two, in accordance with steady-state exit temperature detection, a predetermined timing scheme, or another suitable stratagem. Temperature gradient “flattening”, and improved operating efficiency and PV apparatus longevity, can be achieved accordingly.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. A method, comprising:
providing a photovoltaic apparatus having a photovoltaic coating in contact with a metallic entity, the metallic entity at least partially defining a fluid conduit;
forming at least one electrode by a printing process on the photovoltaic coating;
conducting electrical current generated by the photovoltaic apparatus through an electrical load, the electrical load being coupled to the at least one electrode and the metallic entity; and
transferring thermal energy conducted through the metallic entity to a fluid coolant flowing through the fluid conduit.

14. The method according to claim 13 further comprising:
flowing the fluid coolant through the fluid conduit in a first direction while an exit temperature of the fluid coolant is increasing at greater than a rate value;
sensing that the exit temperature of the fluid coolant is no longer increasing at greater than the rate value; and
flowing the fluid coolant through the fluid conduit in a second direction opposite the first direction.

15. The method according to claim 13 further comprising:
providing the metallic entity in the form of a platen;
applying the photovoltaic coating by roll-to-roll coating a photovoltaic material onto a first surface of the platen;
providing a corrugated metal sheet; and
bonding the corrugated metal sheet to a second surface of the platen such that a plurality of fluid conduits are defined.

16. The method according to claim 13 further comprising:
providing the metallic entity in the form of a tubular conduit; and
applying the photovoltaic coating by dip coating a photovoltaic material onto an outer surface of the tubular conduit, an inner surface of the tubular conduit defining the fluid conduit.

17. The method of claim 13, wherein the printing process includes depositing a conductive ink on the photovoltaic coating.

18. The method of claim 17, wherein depositing the conducting ink includes jet printing the conductive ink.

19. A method, comprising:
providing a photovoltaic coating to a metallic surface;
forming electrodes over the photovoltaic coating using by printing the electrodes on the photovoltaic coating; and
coupling the metallic surface and the electrodes to an electronic circuitry.

20. The method of claim 19, wherein the metallic surface is a metallic tube.

21. The method of claim 20, wherein the photovoltaic coating is provided on an outer surface of the metallic tube.

22. The method of claim 20, further comprising:
fluidly coupling the metallic tube to a fluid coolant system.

23. The method of claim 19, wherein the metallic surface is a metallic plate.

24. The method of claim 23, wherein the photovoltaic coating is provided on a first surface of the metallic plate.

25. The method of claim 24, further comprising:
forming conduits on a second surface of the metallic plate, the second surface being opposite the first surface.

26. The method of claim 25, further comprising:
fluidly coupling the conduits to a fluid coolant system.

27. The method of claim 19, wherein printing the electrodes includes depositing a conductive ink on the photovoltaic coating.

28. The method of claim 27, wherein depositing the conducting ink includes jet printing the conductive ink.
